(19) United States
(12) Patent Application Publication
(10) Pub. No.: US 2026/0101737 A1
(43) Pub. Date: Apr. 9, 2026

(54) SEMICONDUCTOR DEVICE AND MANUFACTURING METHOD THEREOF

(71) Applicant: Samsung Electronics Co., Ltd., Suwon-si (KR)

(72) Inventors: Seungmin LIM, Suwon-si (KR); Eui Bok LEE, Suwon-si (KR); Won Kyu HAN, Suwon-si (KR); Wonhyuk HONG, Suwon-si (KR); Eun-Ji JUNG, Suwon-si (KR)

(73) Assignee: Samsung Electronics Co., Ltd., Suwon-si (KR)

(21) Appl. No.: 19/170,287

(22) Filed: Apr. 4, 2025

(30) Foreign Application Priority Data
Oct. 4, 2024 (KR) 10-2024-0134715

(51) Int. Cl. H01L 23/535; H01L 21/768

(52) U.S. Cl. CPC H10W 20/20; H10W 20/035; H10W 20/0698; H10W 20/076; H10W 20/083

(57) ABSTRACT

Provided is a semiconductor device including a substrate, a source/drain area on the substrate, a first interlayer insulating film on the substrate, a contact plug penetrating at least a portion of the first interlayer insulating film along a first direction perpendicular to a surface of the substrate and electrically connected to the source/drain area, a second interlayer insulating film on the first interlayer insulating film, a wiring via penetrating a portion of the second interlayer insulating film along the first direction and electrically connected to the contact plug, a wiring line penetrating at least a portion of the second interlayer insulating film along the first direction and electrically connected to the wiring via, and a protecting film between the wiring via and the second interlayer insulating film and between the wiring line and the second interlayer insulting film.

### CROSS-REFERENCE TO RELATED APPLICATIONS

This application claims the benefit of Korean Patent Application No. 10-2024-0134715, filed on Oct. 4, 2024, in the Korean Intellectual Property Office, the disclosure of which is incorporated herein by reference in its entirety.

### BACKGROUND

### 1. Field of the Invention

Example embodiments relate to semiconductor devices and methods of manufacturing the semiconductor devices.

### 2. Description of the Related Art

The wiring process (so-called back end of line, BEOL) is the process of connecting components to components and components to the outside. The wiring process may be performed in a dual damascene manner by forming a recess and filling the recess with copper (Cu) to form a via and a line simultaneously. When filling copper, a barrier metal layer and a liner are beneficial in reducing or preventing spiking and to ensure adhesion.

Recently, scaling of wiring is desired due to miniaturization and integration of components. The barrier metal layer and the liner may cause problems such as increased resistance in vias and lines as the area occupied by copper decreases. To improve this, molybdenum (Mo) may be used in the via, which does not require a barrier metal layer or liner. However, when using molybdenum, the insulating layer around the recess may be etched, and the contact to be connected to the via may be damaged.

### SUMMARY

Some aspects provide semiconductor devices by which the insulating layer around the recess is protected and damage to the contact connected to the via is minimized or reduced, and provide methods of manufacturing the semiconductor devices.

The technical tasks to be achieved by the present example embodiments are not limited to the technical tasks described above, and other technical tasks may be inferred from the following example embodiments by those skilled in the art.

According to some aspects, there is provided a semiconductor device including a substrate, a source/drain area on the substrate, a first interlayer insulating film on the substrate, a contact plug penetrating at least a portion of the first interlayer insulating film along a first direction perpendicular to a surface of the substrate and electrically connected to the source/drain area, a second interlayer insulating film on the first interlayer insulating film, a wiring via penetrating a portion of the second interlayer insulating film along the first direction and electrically connected to the contact plug, a wiring line penetrating at least a portion of the second interlayer insulating film along the first direction and electrically connected to the wiring via, and a protecting film between the wiring via and the second interlayer insulating film and between the wiring line and the second interlayer insulting film.

According to some aspects, there is provided a method of manufacturing a semiconductor device, the method including, forming a recessed portion in a semi-finished product including a substrate, a source/drain area on the substrate, a first interlayer insulating film on the substrate, a contact plug penetrating at least a portion of the first interlayer insulating film along a first direction perpendicular to a surface of the substrate and electrically connected to the source/drain area and a second interlayer insulating film on the first interlayer insulating film, by etching the second interlayer insulating film along the first direction until the contact plug is exposed, forming a protecting film on at least an inner wall of the recessed portion, forming a wiring via to be electrically connected to the contact plug, and forming a wiring line to be electrically connected to the wiring via.

According to some aspects, there is provided a substrate, a source/drain area on the substrate, a first interlayer insulating film on the substrate, a contact plug penetrating at least a portion of the first interlayer insulating film along a first direction perpendicular to a surface of the substrate and electrically connected to the source/drain area, a second interlayer insulating film on the first interlayer insulating film, a wiring via penetrating a portion of the second interlayer insulating film along the first direction and electrically connected to the contact plug, a wiring line penetrating at least a portion of the second interlayer insulating film along the first direction and electrically connected to the wiring via, a protecting film between the wiring via and the second interlayer insulating film and between the wiring line and the second interlayer insulting film, and including silicon oxide, a barrier film between the protecting film and the wiring line and surrounding at least a portion of the wiring via, a liner film between the barrier film and the wiring line and surrounding at least a portion of the wiring via, and an interlayer etching stopping film between the first interlayer insulating film and the second interlayer insulating film, wherein the wiring via penetrates a portion of the first interlayer insulating film and the interlayer etching stopping film along the first direction, the wiring via includes a first via area surrounded by the first interlayer insulating film and a second via area that is an area other than the first via area, the first via area includes a via area 1-1 that is adjacent to the contact plug and a via area 1-2 that is an area other than the via area 1-1, the via area 1-1 has a grain size that is smaller than a grain size of the via area 1-2, and the grain size of the via area 1-1 is smaller than the grain size of the second via area.

Specific details of example embodiments are included in the detailed description and drawings.

### BRIEF DESCRIPTION OF THE FIGURES

These and/or other aspects, features, and advantages of the inventions will become apparent and more readily appreciated from the following description of some example embodiments, taken in conjunction with the accompanying drawings of which:

FIG. 1 is a drawing illustrating a cross-section of a semiconductor device according to some example embodiments;

FIG. 2 is an enlarged view of a portion P of FIG. 1;

FIG. 3 is a drawing illustrating a cross-section of a semiconductor device according to some example embodiments;

FIG. 4 is an enlarged view of a portion Q of FIG. 3;

FIG. 5 is a drawing illustrating a semi-finished product to explain a method for manufacturing a semiconductor device according to some example embodiments, and illustrates the process of preparing for the etching process;

FIG. 6 is a drawing illustrating a semi-finished product to explain a method for manufacturing a semiconductor device according to some example embodiments, and illustrates the process of forming a recessed portion;

FIG. 7 is a drawing illustrating a semi-finished product to explain a method for manufacturing a semiconductor device according to some example embodiments, and illustrates the process of depositing an inhibitor;

FIG. 8 is a drawing illustrating a semi-finished product to explain a method for manufacturing a semiconductor device according to some example embodiments, and illustrates the process of forming a pre-protecting film;

FIG. 9 is a drawing illustrating a semi-finished product to explain a method for manufacturing a semiconductor device according to some example embodiments, and illustrates the process of removing an inhibitor;

FIG. 10 is a drawing illustrating a semi-finished product to explain a method for manufacturing a semiconductor device according to some example embodiments, and illustrates the process of forming a protecting film;

FIG. 11 is a drawing illustrating a semi-finished product to explain a method for manufacturing a semiconductor device according to some example embodiments, and illustrates the process of forming a wiring via;

FIG. 12 is a drawing illustrating a semi-finished product to explain a method for manufacturing a semiconductor device according to some example embodiments, and illustrates the process of forming a barrier film;

FIG. 13 is a drawing illustrating a semi-finished product to explain a method for manufacturing a semiconductor device according to some example embodiments, and illustrates the process of forming a liner film;

FIG. 14 is a drawing illustrating a semi-finished product to explain a method for manufacturing a semiconductor device according to some example embodiments, and illustrates the process of forming a wiring line;

FIG. 15 is a drawing for explaining a method for manufacturing a semiconductor device according to some example embodiments, and illustrates the result after chemical mechanical polishing (CMP);

FIG. 16 is a drawing illustrating a semi-finished product to explain a method for manufacturing a semiconductor device according to some example embodiments, and illustrates the process of forming a via area 1-1;

FIG. 17 is a drawing illustrating a semi-finished product to explain a method for manufacturing a semiconductor device according to some example embodiments, and illustrates the process of forming a via area 1-2;

FIG. 18 is a drawing illustrating a semi-finished product to explain a method for manufacturing a semiconductor device according to some example embodiments, and illustrates the process of forming a wiring via;

FIG. 19 is a drawing illustrating a semi-finished product to explain a method for manufacturing a semiconductor device according to some example embodiments, and illustrates the process of forming a barrier film;

FIG. 20 is a drawing illustrating a semi-finished product to explain a method for manufacturing a semiconductor device according to some example embodiments, and illustrates the process of forming a liner film;

FIG. 21 is a drawing illustrating a semi-finished product to explain a method for manufacturing a semiconductor device according to some example embodiments, and illustrates the process of forming a wiring line; and

FIG. 22 is a drawing for explaining a method for manufacturing a semiconductor device according to some example embodiments, and illustrates the result after the CMP.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with the technical ideas of the present disclosure based on the principle that the inventor may appropriately define the concept of terms in order to explain his or her inventions in the best way. The example embodiments described in this specification and the configurations shown in the drawings are only some of the embodiments of the present disclosure, and do not necessarily represent the entire technical ideas of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different example embodiments may be described using the same reference numerals or symbols. In other words, even if a component or an element having the same reference numeral is shown in multiple drawings, the multiple drawings may not all represent one example embodiment.

In the present disclosure, when an element is described as being “directly on,” “adjacent to” or “in contact with” another element, the element may be understood as being in direct contact with or connected to the another element, and it may be understood that there is no other element between the two.

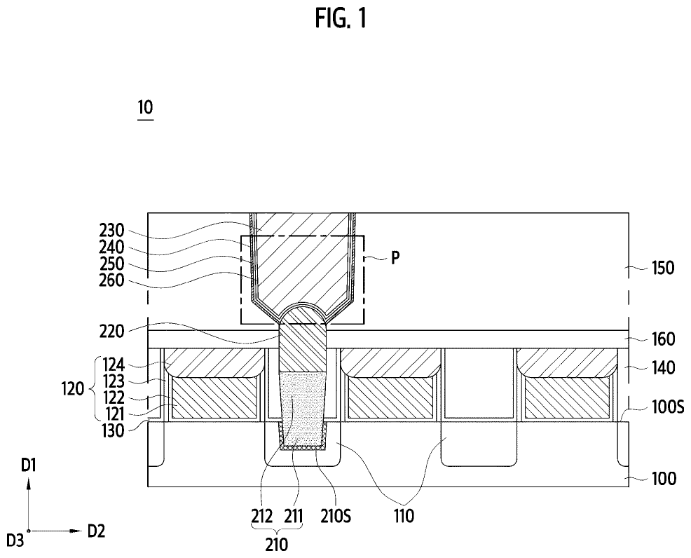

Further, in the present disclosure, when an element is described as being “on an upper portion” or “on an upper surface” of another element, it may be understood as existing above the vertical direction, for example, as being above the +D1 direction in the drawing (see FIG. 1), and the two elements may be in direct contact or connected, but it may also be understood that another element exists between the two. The same is applied even when an element is described as being “above” another element in the present disclosure.

Further, in the present disclosure, when an element is described as being “underneath” another element, it may be understood as existing below based on the vertical direction, for example, being further below based on the −D1 direction in the drawing (see FIG. 1), and the two elements may be in direct contact or connected, but it may also be understood that another element exists between the two. The same is applied even when an element is described as being “beneath” another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side, and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

The properties described in the present disclosure may be measured in a room temperature and pressure environment unless specifically limited. In the present disclosure, as the natural temperature without any artificial manipulation, the room temperature can be about or exactly 10° C. to about or exactly 30° C., about or exactly 20° C. to about or exactly 28° C. or about or exactly 22° C. to about or exactly 26° C. In some example embodiments, the room temperature can be about or exactly 25° C. In some example embodiments, as a natural pressure without any artificial manipulation, the pressure may be between about or exactly 700 mmHg and about or exactly 800 mmHg or between about or exactly 720 mmHg and about or exactly 780 mmHg, and in one example embodiment may be about or exactly 760 mmHg.

The drawings illustrated in the present disclosure are according to mere example embodiments, and the ratio of the width, the length, and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the − direction.

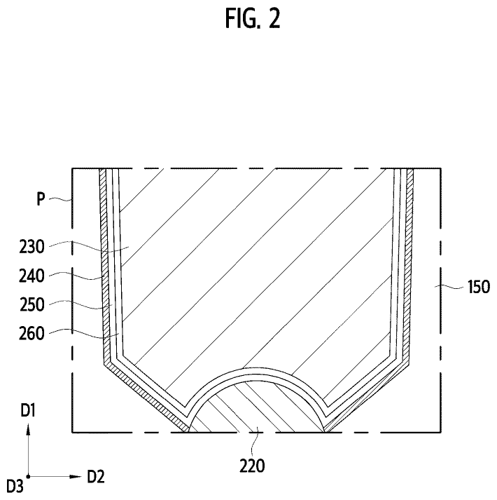

Hereinafter, example embodiments according to the technical ideas of the present inventions will be described with reference to the attached drawings. FIG. 1 is a drawing illustrating a cross-section of a semiconductor device 10 according to some example embodiments. FIG. 2 is an enlarged view of a portion P of FIG. 1.

In some example embodiments, the semiconductor device 10 may include a substrate 100, a source/drain area 110, a first interlayer insulating film 140, a contact plug 210, a second interlayer insulating film 150, a wiring via 220, a wiring line 230 and a protecting film 240.

In the present disclosure, the first direction D1 may indicate the vertical direction of a surface 100S of the substrate. The second direction D2 may indicate a direction that intersects the first direction D1. In some example embodiments, the second direction D2 may be about or exactly identical to or parallel to the horizontal direction of the surface 100S of the substrate. The third direction D3 may indicate a direction that intersects the first direction D1 and the second direction D2. In some example embodiments, the third direction D3 may be about or exactly identical to or parallel to the horizontal direction of the surface 100S of the substrate. In some example embodiments, the first direction D1 and the second direction D2 may be perpendicular to each other. The second direction D2 and the third direction D3 may be perpendicular to each other. The third direction D3 and the first direction D1 may be perpendicular to each other.

In some example embodiments, the substrate 100 may be a silicon substrate or a silicon-on-insulator (SOI). The substrate 100 may include silicon germanium, silicon germanium on insulator (SGOI), indium antimonide, lead telluride, indium arsenide, indium phosphide, gallium arsenide and/or gallium antimonide. However, the substrate 100 is not limited thereto. In some example embodiments, the substrate 100 may include at least one selected from the group consisting of silicon oxide, silicon nitride, silicon oxynitride, a low-k material, and a high-k material. However, the substrate 100 is not limited thereto. In the present disclosure, low-k materials may have the dielectric constant less than about or exactly 3.9 to 0. For example, the low-k materials may include at least one of a group consisting of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilyl Phosphate (TMSP), PolyTetraFluoroEthylene (PTFE), TOSZ (Tonen SilaZen), FSG (Fluoride Silicate Glass), polyimide, polypropylene oxide, Carbon Doped silicon Oxide (CDO), Organo Silicate Glass (OSG), SiLK, Amorphous Fluorinated Carbon, silica aerogels, silica xerogels and mesoporous silica. However, the low-k materials are not limited thereto. In the present disclosure, high-k materials may have dielectric constants greater than about or exactly 3.9 up to about or exactly 1000. For example, the high-k materials may include one or more of the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate. However, the high-k materials are not limited thereto.

In some example embodiments, the source/drain area 110 may be formed in the substrate 100. There may be a plurality of source/drain areas 110, and the source/drain areas 110 may be separated from each other. For example, the source/drain areas 110 may be spaced apart from each other in the second direction D2.

In some example embodiments, the source/drain area 110 may contain impurities, the types of which may vary depending on the conductivity type. For example, the N-type may include an N-type dopant, which is an impurity including at least one of phosphorus (P), arsenic (As), antimony (Sb) and bismuth (Bi). The P-type may include a P-type dopant, which is an impurity including at least one of boron (B) and gallium (Ga). At least some of the plurality of source/drain areas 110 may be N-type or P-type. Some of the plurality of source/drain areas 110 may be N-type and the others may be P-type.

In some example embodiments, the first interlayer insulating film 140 may be placed on the substrate 100. The first interlayer insulating film 140 may be placed on the substrate 100 in the first direction D1. In some cases, the first interlayer insulating film 140 may be in contact with at least a portion of the substrate 100.

In some example embodiments, the first interlayer insulating film 140 may include at least one selected from the group consisting of silicon oxide, silicon nitride, silicon oxynitride, a low-k material and a high-k material. However, the first interlayer insulating film 140 is not limited thereto. The first interlayer insulating film 140 may include, for example, a low-k material.

In some example embodiments, the semiconductor device 10 may include a gate structure 120. When viewed in the first direction, the gate structure 120 may not overlap with the source/drain area 110. In some example embodiments, there may be a plurality of gate structures 120, and the plurality of gate structures 120 may be spaced apart from each other. For example, the plurality of gate structures 120 may be spaced apart from each other in the second direction D2.

In some example embodiments, there may be three or more gate structures 120, and the spacing between adjacent gate structures 120 among three or more gate structures 120 may be the same or substantially the same.

In some example embodiments, the gate structure 120 may include a gate electrode 121, a gate insulating film 122, a gate spacer 123 and a gate capping film 124. In some example embodiments, the gate electrode 121 may be arranged to extend in the third direction D3. In some example embodiments, there may be a plurality of gate electrodes 121, and the plurality of gate electrodes 121 may be spaced apart from each other. For example, the plurality of gate electrodes 121 may be spaced apart from each other in the second direction D2.

In some example embodiments, at least some of the plurality of gate electrodes 121 may be normal gate electrodes used as gates of the transistor, and the other gate electrodes 121 may be dummy gate electrodes.

In some example embodiments, the gate electrode 121 may include a conductive material. Here, the conductive material may include at least one selected from the group consisting of doped polysilicon, metals, metal nitrides, metal silicides, and metal oxides. In some example embodiments, the metal may include one or more selected from the group consisting of aluminum (Al), copper (Cu), titanium (Ti), tantalum (Ta), rubidium (Ru), tungsten (W), molybdenum (Mo), platinum (Pt), nickel (Ni), tin (Sn), lead (Pb) and cobalt (Co). In some example embodiments, the metal nitride may include one or more selected from the group consisting of titanium nitride (TiN), titanium aluminum nitride (TiAlN), tantalum silicon nitride (TaSiN) and rubidium titanium nitride (RuTiN). In some example embodiments, the metal silicide may include at least one selected from the group consisting of titanium silicide (TiSi), tantalum silicide (TaSi), nickel silicide (NiSi) and cobalt silicide (CoSi). In some example embodiments, the metal oxide may include at least one selected from the group consisting of iridium oxide (IrOₓ) and rubidium oxide (RuOₓ).

In some example embodiments, the gate insulating film 122 of the gate structure 120 may surround at least a portion of the gate electrode 121. The gate insulating film 122 may include at least one selected from the group consisting of silicon oxide, silicon nitride, silicon oxynitride, a low-k material and a high-k material. However, the gate insulating film 122 is not limited thereto.

In some example embodiments, the gate spacer 123 of the gate structure 120 may surround at least a portion of the gate insulating film 122. The gate spacer 123 may include one or more selected from the group consisting of silicon oxide, silicon nitride, silicon oxynitride, a low-k material and a high-k material. However, the gate spacer 123 is not limited thereto.

In some example embodiments, in some cases, the gate structure may include a high-k interfacial layer (not illustrated) placed between the gate insulating film 122 and the gate spacer 123. In some example embodiments, a material included in the high-k interface layer may have a higher dielectric constant than a material included in the gate insulating film 122 and the gate spacer 123.

In some example embodiments, the gate capping film 124 of the gate structure 120 may surround at least a portion of each of the gate spacer 123 and the gate electrode 121. The gate capping film 124 may include at least one selected from the group consisting of silicon oxide, silicon nitride, silicon oxynitride, a low-k material and a high-k material. However, the gate capping film 124 is not limited thereto.

In some cases, in some example embodiments, the semiconductor device 10 may include a source/drain etching stopping film 130 positioned between the gate structure 120 and the first interlayer insulating film 140 and between the source/drain area 110 and the first interlayer insulating film 140. In some example embodiments, the source/drain etching stopping film 130 may include at least one selected from the group consisting of silicon nitride (SiN), silicon oxynitride (SiON), silicon oxycarbonitride (SiOCN), silicon boron nitride (SiBN), silicon oxyboron nitride (SiOBN) and silicon oxycarbide (SiOC).

In some example embodiments, the second interlayer insulating film 150 may be placed on the substrate 100. The second interlayer insulating film 150 may be spaced apart and arranged on the substrate 100 in the first direction D1. In some example embodiments, the second interlayer insulating film 150 may include at least one selected from the group consisting of silicon oxide, silicon nitride, silicon oxynitride, a low-k material and a high-k material. However, the second interlayer insulating film 150 is not limited thereto. The second interlayer insulating film 150 may include, for example, a low-k material.

In some example embodiments, the second interlayer insulating film 150 may not have an etching stopping film formed. The second interlayer insulating film 150 may be a single layer, or a multilayer structure containing the same material. Even if the second interlayer insulating film 150 has the multilayer structure, it may be difficult to distinguish between layers.

In some example embodiments, the semiconductor device 10 may be manufactured, for example, using a dual damascene method as opposed to a single damascene method. Thus, an etching stopping film may not be formed between the wiring via 220 and the wiring line 230. In some example embodiments, the second interlayer insulating film 150 may wrap at least a portion of each of the wiring via 220 and the wiring line 230. In some example embodiments, the second interlayer insulating film 150 may wrap a portion of the wiring via 220 and the wiring line 230.

In some example embodiments, the semiconductor device 10 may include an interlayer etching stopping film 160 placed between the first interlayer insulating film 140 and the second interlayer insulating film 150. In some example embodiments, the interlayer etching stopping film 160 may include at least one selected from the group consisting of silicon nitride (SiN), silicon oxynitride (SiON), silicon oxycarbonitride (SiOCN), silicon boron nitride (SiBN), silicon oxyboron nitride (SiOBN) and silicon oxycarbide (SiOC).

In some example embodiments, the contact plug 210 may penetrate at least a portion of the first interlayer insulating film 140 along the first direction D1 and be electrically connected to the source/drain area 110. In some example embodiments, the contact plug 210 may include a metal material. In the present disclosure, the metal material is not particularly limited, but may include one or more selected from the group consisting of, for example, copper (Cu), aluminum (Al), chromium (Cr), vanadium (V), titanium (Ti), tantalum (Ta), rubidium (Ru), tungsten (W), molybdenum (Mo), platinum (Pt), nickel (Ni), tin (Sn), lead (Pb) and cobalt (Co). In some example embodiments, the contact plug 210 may include copper (Cu). In some example embodiments, the contact plug 210 may have an electrical conductivity of about or exactly 1×10⁶ S/m or greater (up to, for example, 6×10⁷ S/m) at 20° C.

In some example embodiments, the contact plug 210 may include a first contact area 211 surrounded by the source/drain area 110, and a second contact area 212 that is an area other than the first contact area 211. In some example embodiments, the contact plug 210 may include a silicide layer 210S between the first contact area 211 and the source/drain area 110 of the contact plug 210. In some example embodiments, the silicide layer 210S may be a metal silicide, which is a silicide of a metal material. The silicide layer 210S may allow ohmic contact between the contact plug 210 and the source/drain area 110.

In some example embodiments, the wiring via 220 may penetrate a portion of the second interlayer insulating film 150 along the first direction D1 and be electrically connected to the contact plug 210. In some example embodiments, the wiring via 220 may include a metal material. In some example embodiments, the wiring via 220 may include molybdenum (Mo). In some example embodiments, the wiring via 220 may have an electrical conductivity of about or exactly 1×10⁶ S/m or greater (up to, for example, 6×10⁷ S/m) at t 20° C. The melting point of the wiring via 220 may be higher than the melting point of the contact plug 210.

In some example embodiments, the wiring via 220 may penetrate the interlayer etching stopping film 160 along the first direction D1. The wiring via 220 may penetrate a portion of the first interlayer insulating film 140 along the first direction D1.

In some example embodiments, the wiring via 220 may overlap at least partially with the contact plug 210 when viewed in the first direction D1. In some example embodiments, the wiring via 220 may be spaced apart from the gate structure 120. Specifically, the wiring via 220 may be spaced apart from the gate structure 120 along the second direction D2.

In some example embodiments, the wiring line 230 may penetrate at least a portion of the second interlayer insulating film 150 along the first direction D1 and be electrically connected to the wiring via 220. In some example embodiments, the wiring line 230 may include a metallic material. In some example embodiments, the wiring line 230 may include copper (Cu). In some example embodiments, the wiring line 230 may have an electrical conductivity of 1×10⁶ S/m or greater at 20° C. (e.g., up to 6×10⁷ S/m). The melting point of the wiring line 230 may be lower than the melting point of the wiring via 220.

In some example embodiments, the wiring line 230 may be formed to extend in the second direction D2. The wiring line 230 may be formed to extend further in the other direction. The wiring line 230 may partially penetrate the second interlayer insulating film 150 along the first direction D1.

In some example embodiments, the wiring line 230 may overlap at least partially with the contact plug 210 when viewed in the first direction D1. The wiring line 230 may overlap at least partially with the wiring via 220 when viewed from the first direction D1. The wiring line 230 may overlap at least partly with the contact plug 210 and the wiring via 220 when viewed in the first direction D1.

In some example embodiments, the protecting film 240 may be placed between the wiring via 220 and the second interlayer insulating film 150 and the protecting film 240 may be placed between the wiring line 230 and the second interlayer insulating film 150. In some example embodiments, the protecting film 240 may include at least one selected from the group consisting of silicon oxide, silicon nitride (SiN), silicon oxynitride (SiON), silicon oxycarbonitride (SiOCN), silicon boron nitride (SiBN), silicon oxyboron nitride (SiOBN) and silicon oxycarbide (SiOC). For example, the protecting film 240 may contain silicon oxide (SiO₂). The protecting film 240 may protect the second interlayer insulating film 150 and minimize damage to the contact plug 210.

In some example embodiments, the semiconductor device 10 may include a barrier film 250 positioned between the protecting film 240 and the wiring line 230. The barrier film 250 may wrap at least a portion of the wiring via 220. The barrier film 250 may be formed between the wiring via 220 and the wiring line 230. In some cases, the barrier film 250 may contact at least a portion of the wiring via 220.

In some example embodiments, the barrier film 250 may include one or more selected from the group consisting of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) and two-dimensional materials (2D materials).

In the present disclosure, the 2D material may be a metallic material and/or a semiconductor material. The 2D material may include a 2D allotrope or a 2D compound. The 2D material may include, for example, one or more of graphene, molybdenum disulfide (MoS₂), molybdenum diselenide (MoSe₂), tungsten diselenide (WSe₂), and tungsten disulfide (WS₂). However, the 2D material is not limited thereto.

In some example embodiments, the semiconductor device may include a liner film 260 positioned between the barrier film 250 and the wiring line 230. The liner film 260 may wrap at least a portion of the wiring via 220. The liner film 260 may be formed on the barrier film 250. The liner film 260 may be formed between the wiring via 220 and the wiring line 230. The liner film 260 may be formed between the barrier film 250 and the wiring line 230. The liner film 260 may be spaced apart from the wiring via 220.

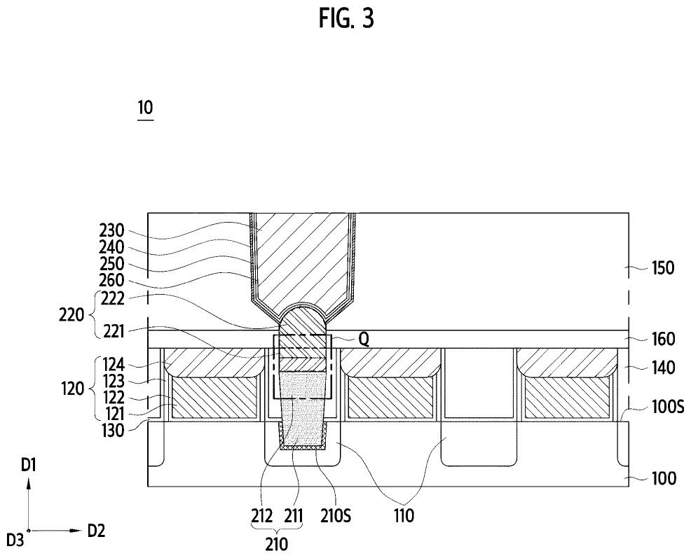

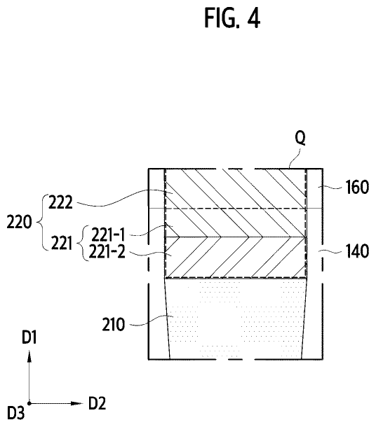

FIG. 3 is a drawing illustrating a cross-section of the semiconductor device 10 according to some example embodiments. FIG. 4 is an enlarged view of a portion Q of FIG. 3.

In some example embodiments, the wiring via 220 may include a first via area 221 surrounded by the first interlayer insulating film 140 and a second via area 222 that is an area other than the first via area 221. In some example embodiments, the first via area 221 may include a via area 1-1 221-1 adjacent to the contact plug 210 and a via area 1-2 221-2 that is an area other than the via area 1-1 221-1.

In some example embodiments, the grain size of the via area 1-1 221-1 may be smaller than the grain size of the via area 1-2 221-2. Through this, the via area 1-1 221-1 may act as a protective layer to minimize or reduce damage to the contact plug 210, and through the via area 1-2 221-2, the increase in resistance of the wiring via 220 and the wiring line 230 may be minimized or reduced even when components are miniaturized and integrated. The grain size of the via area 1-1 221-1 and grain size of the via area 1-2 221-2, as will be described later, may be controlled by adjusting the flow of precursor forming each via area (the via area 1-1 221-1, and the via area 1-2 221-2). Increasing the flow of precursors, for example, may increase the grain size.

In the present disclosure, the grain size may be measured via transmission electron microscope (TEM) using a precession electron diffraction (PED) method. For example, the grain size may be measured according to the Zimmer method, also known as the circle method.

In some example embodiments, the grain size of the via area 1-1 221-1 measured according to the Zimmer method may be about or exactly 5 nm² or less, about or exactly 4.5 nm² or less, about or exactly 4 nm² or less, about or exactly 3.5 nm² or less, or about or exactly 3 nm² or less. In some example embodiments, the grain size of the via area 1-1 221-1 measured according to the Zimmer method may be greater than 0 nm². In some example embodiments, the grain size of the via area 1-2 221-2 measured according to the Zimmer method may be greater than about or exactly 5 nm², about or exactly 5.5 nm² or greater, about or exactly 6 nm² or greater, about or exactly 6.5 nm² or greater, about or exactly 7 nm² or greater, about or exactly 7.5 nm² or greater, about or exactly 8 nm² or greater, about or exactly 8.5 nm² or greater, about or exactly 9 nm² or greater, about or exactly 9.5 nm² or greater, or about or exactly 10 nm² or greater. In some example embodiments, the grain size of the via area 1-2 221-2 measured according to the Zimmer method may be about or exactly 20 nm² or less, about or exactly 19 nm² or less, about or exactly 18 nm² or less, about or exactly 17 nm² or less, about or exactly 16 nm² or less, or about or exactly 15 nm² or less.

In some example embodiments, the grain size of the via area 1-1 221-1 may be smaller than the grain size of the second via area 222. In some example embodiments, the grain size of the via area 1-2 221-2 may be the same or substantially the same as the grain size of the second via area 222.

In some example embodiments, the grain size of the second via area 222 measured by the Zimmer method may be greater than about or exactly 5 nm², about or exactly 5.5 nm² or greater, about or exactly 6 nm² or greater, about or exactly 6.5 nm² or greater, about or exactly 7 nm² or greater, about or exactly 7.5 nm² or greater, about or exactly 8 nm² or greater, about or exactly 8.5 nm² or greater, about or exactly 9 nm² or greater, about or exactly 9.5 nm² or greater, or about or exactly 10 nm² or greater. In some example embodiments, the grain size of the second via area 222 measured according to the Zimmer method may be about or exactly 20 nm² or less, about or exactly 19 nm² or less, about or exactly 18 nm² or less, about or exactly 17 nm² or less, about or exactly 16 nm² or less, or about or exactly 15 nm² or less.

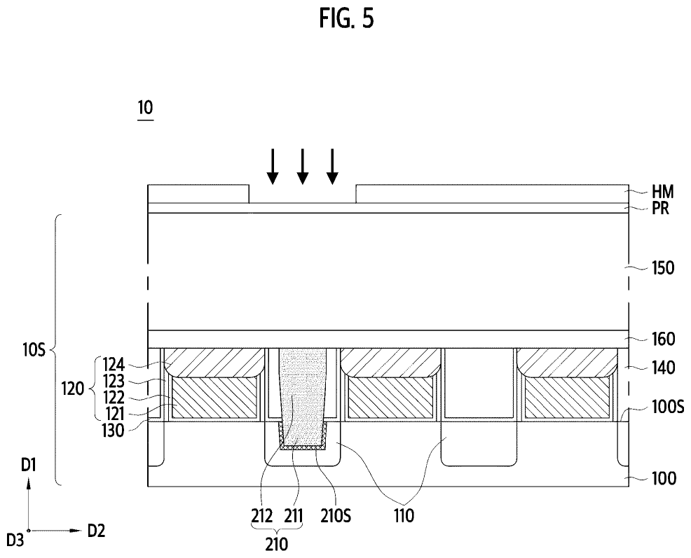

FIG. 5 is a drawing illustrating a semi-finished product 10S to explain a method for manufacturing the semiconductor device 10 according to some example embodiments, and illustrates the process of preparing for the etching process.

Referring to FIG. 5, in some example embodiments, a method of manufacturing the semiconductor device 10 may include applying a photoresist PR on the semi-finished product 10S, with respect to the semi-finished product 10S including the substrate 100, the source/drain area 110, the first interlayer insulating film 140, the contact plug 210 and the second interlayer insulating film 150. In some example embodiments, the method of manufacturing the semiconductor device 10 may include disposing a hard mask HM on the photoresist PR. In some example embodiments, a method of manufacturing the semiconductor device 10 may include applying an energy line to a portion of the photoresist PR having the hard mask HM placed thereon. In other words, the method of manufacturing the semiconductor device 10 may include performing a photo process. The open area of the hard mask HM may overlap at least a portion of the contact plug 210 when viewed in the first direction D1.

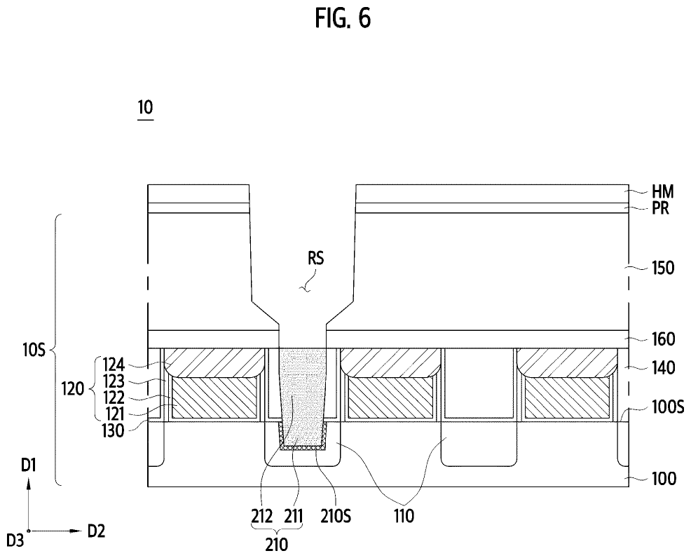

FIG. 6 is a drawing illustrating the semi-finished product 10S to explain a method for manufacturing the semiconductor device 10 according to some example embodiments, and illustrates the process of forming a recessed portion RS. In some example embodiments, the method for manufacturing the semiconductor device 10 may include forming the recessed portion RS through the photo process described above. In some example embodiments, the method of manufacturing the semiconductor device 10 may include forming the recessed portion RS by etching the second interlayer insulating film 150 along the first direction D1 until the contact plug 210 is exposed.

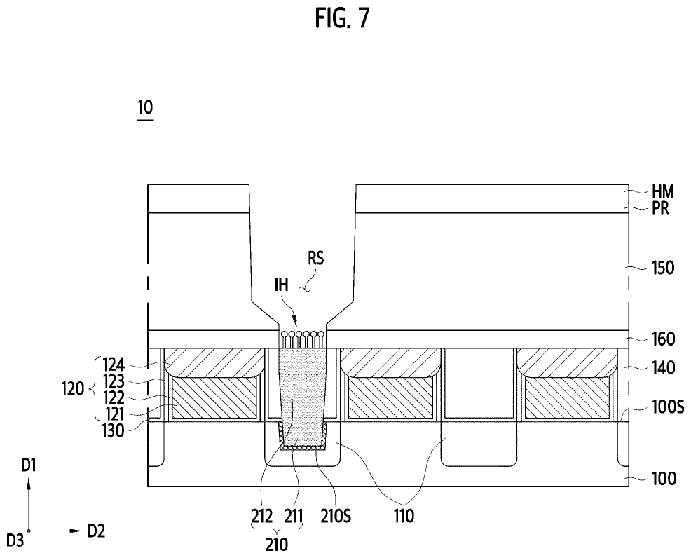

FIG. 7 is a drawing illustrating a semi-finished product to explain a method for manufacturing the semiconductor device 10 according to some example embodiments, and illustrates the process of depositing an inhibitor IH. In some example embodiments, a method of manufacturing the semiconductor device 10 may include forming the inhibitor IH on an area where the contact plug 210 is exposed. The inhibitor IH may include a compound including a polar functional group and a carbon chain to which the polar functional group is bonded. The polar functional group of the inhibitor IH may be connected to the contact plug 210. The connection at this time may be either a chemical bond or physical adsorption. Further, for example, the inhibitor IH may be a self-assembly monolayer polymer. In some example embodiments, the inhibitor IH is not particularly limited, but may be formed via chemical vapor deposition (CVD).

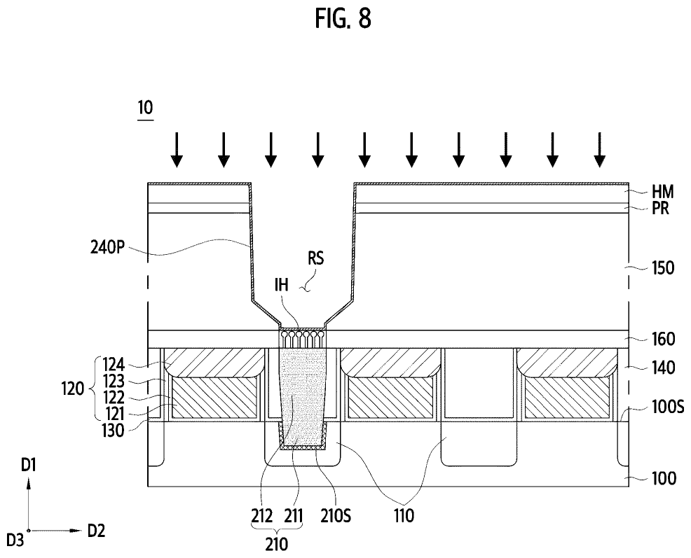

FIG. 8 is a drawing illustrating a semi-finished product to explain a method for manufacturing the semiconductor device 10 according to some example embodiments, and illustrates the process of forming a pre-protecting film 240P. In some example embodiments, a method for manufacturing the semiconductor device 10 may include forming the pre-protecting film 240P on at least an inner wall of the recessed portion RS. In some example embodiments, the pre-protecting film 240P may include at least one selected from the group consisting of silicon oxide, silicon nitride (SiN), silicon oxynitride (SiON), silicon oxycarbonitride (SiOCN), silicon boron nitride (SiBN), silicon oxyboron nitride (SiOBN), and silicon oxycarbide (SiOC). For example, the pre-protecting film 240P may contain silicon oxide (SiO₂). In some example embodiments, the pre-protecting film 240P may be formed through deposition. For example, the pre-protecting film 240P may be formed through the CVD, physics vapor deposition (PVD) or atomic layer deposition (ALD).

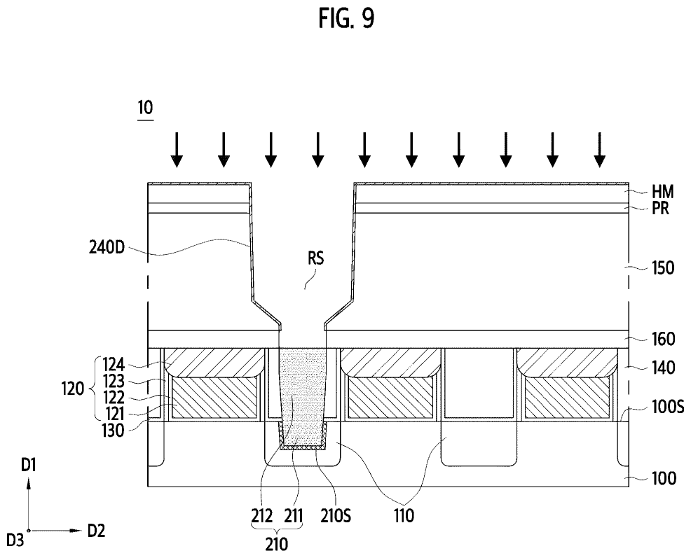

FIG. 9 is a drawing illustrating a semi-finished product to explain a method for manufacturing the semiconductor device 10 according to some example embodiments, and illustrates the process of removing the inhibitor IH. In some example embodiments, a method of manufacturing the semiconductor device 10 may include removing the inhibitor IH. In some example embodiments, the inhibitor IH may be removed via plasma. Here, the pre-protecting film 240P that has already been formed may become a pre-protecting film 240D that has been damaged by plasma, etc.

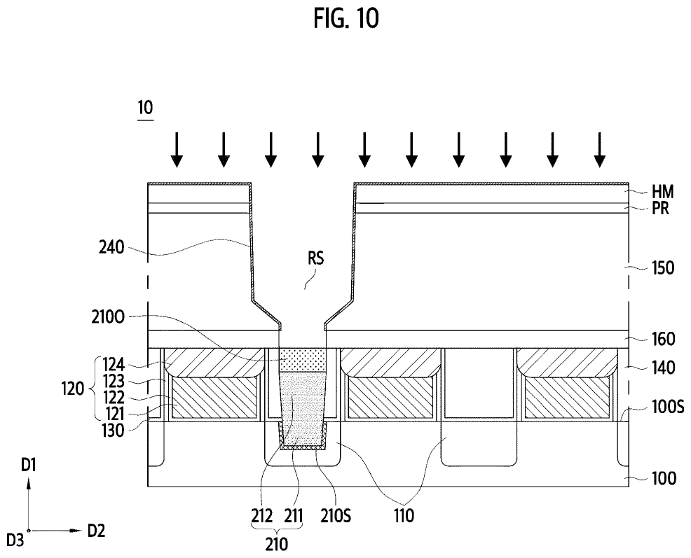

FIG. 10 is a drawing illustrating a semi-finished product to explain a method for manufacturing the semiconductor device 10 according to some example embodiments, and illustrates the process of forming the protecting film 240. In some example embodiments, a method of manufacturing the semiconductor device 10 may include forming the protecting film 240 on at least an inner wall of the recessed portion RS. In some example embodiments, the damaged pre-protecting film 240D may be treated to form the protecting film 240. The method manufacturing the semiconductor device 10 may form the damaged pre-protecting film 240D into the protecting film 240 through, for example, oxygen curing. Here, through the oxygen curing, a contact oxide film 210O may be formed in some areas adjacent to the recessed portion RS of the contact plug 210. In other words, in some example embodiments, in a method for manufacturing the semiconductor device 10, forming the protecting film 240 may include forming the contact oxide film 210O in a portion of the contact plug 210 adjacent to the recessed portion RS.

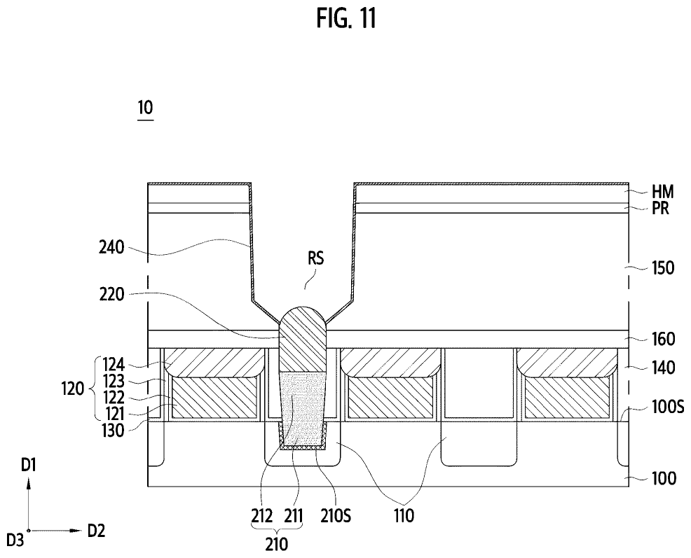

FIG. 11 is a drawing illustrating a semi-finished product to explain a method for manufacturing the semiconductor device 10 according to some example embodiments, and illustrates the process of forming the wiring via 220. In some example embodiments, a method of manufacturing the semiconductor device 10 may include forming the wiring via 220 to be electrically connected to the contact plug 210. In some example embodiments, in a method of manufacturing the semiconductor device 10, forming the wiring via 220 may include removing the contact oxide film 210O. The contact oxide film 210O may be naturally removed while the wiring via 220 being formed, e.g., the contact oxide film 210O may be removed as an effect of forming the wiring without additional processing.

In some example embodiments, the wiring via 220 may be formed by injecting a metal halide. The precursor forming each of the above-mentioned via areas (the via area 1-1 221-1, and the via area 1-2 221-2) may be a metal halide. The metal halide may include one selected from the group consisting of, for example, copper (Cu), aluminum (Al), chromium (Cr), vanadium (V), titanium (Ti), tantalum (Ta), rubidium (Ru), tungsten (W), molybdenum (Mo), platinum (Pt), nickel (Ni), tin (Sn), lead (Pb), and cobalt (Co), and/or one selected from the group consisting of fluorine (F), chlorine (Cl), bromine (Br), and iodine (I). For example, the metal halide may include one or more selected from the group consisting of molybdenum hexafluoride (MoF₆) and molybdenum pentachloride (MoCl₅). When forming the wiring via 220, an inert gas may be mixed with the metal halide. The inert gas may include one or more selected from the group consisting of, for example, helium (He), neon (Ne) and argon (Ar). In some example embodiments, the wiring via 220 may be formed by deposition through a metal halide.

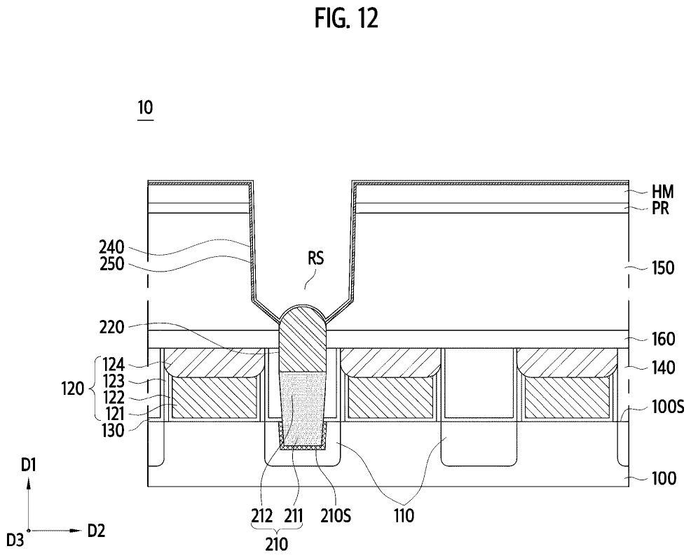

FIG. 12 is a drawing illustrating a semi-finished product to explain a method for manufacturing the semiconductor device 10 according to some example embodiments, and illustrates the process of forming the barrier film 250. In some example embodiments, a method of manufacturing a semiconductor device 10 may include forming a barrier film 250 over at least a portion of a protecting film 240 and a wiring via 220. In some example embodiments, the barrier film 250 may be formed via deposition. For example, the barrier film 250 may be formed via the CVD, the PVD or the ALD.

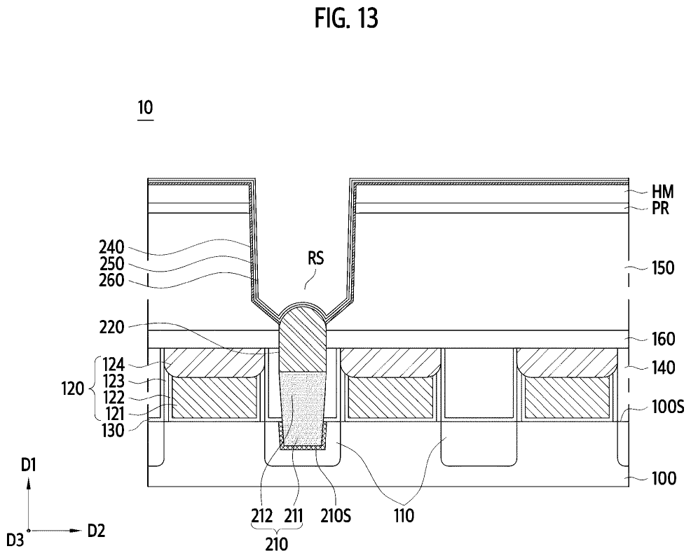

FIG. 13 is a drawing illustrating a semi-finished product to explain a method for manufacturing the semiconductor device 10 according to some example embodiments, and illustrates the process of forming the liner film 260. In some example embodiments, a method of manufacturing the semiconductor device 10 may include forming the liner film 260 over at least a portion of the barrier film 250. In some example embodiments, the liner film 260 may be formed via deposition. For example, the liner film 260 may be formed through the CVD, the PVD or the ALD.

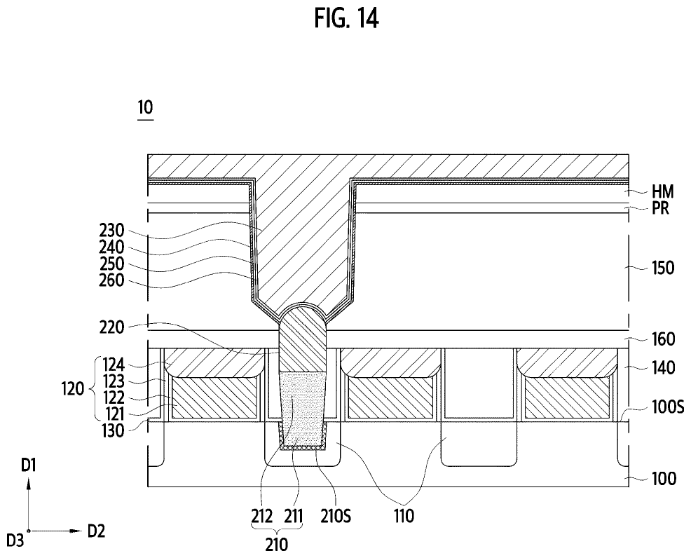

FIG. 14 is a drawing illustrating a semi-finished product to explain a method for manufacturing the semiconductor device 10 according to some example embodiments, and illustrates the process of forming the wiring line 230. In some example embodiments, a method of manufacturing the semiconductor device 10 may include forming the wiring line 230 to be electrically connected to the wiring via 220. In some example embodiments, the wiring line 230 may be formed through deposition. For example, the wiring line 230 may be formed through the CVD, the PVD or the ALD. In some example embodiments, a method of manufacturing the semiconductor device 10 may include forming the wiring line 230 to fill the recessed portion RS.

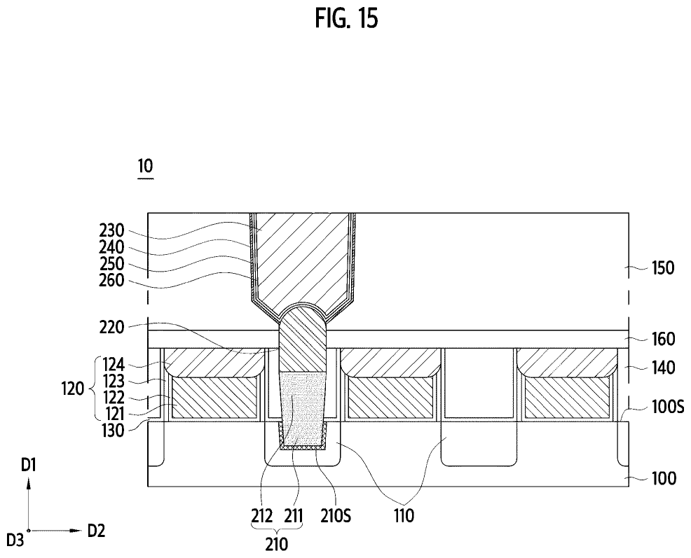

FIG. 15 is a drawing for explaining a method for manufacturing a semiconductor device according to some example embodiments, and illustrates the result after the CMP. In some example embodiments, a method of manufacturing the semiconductor device 10 may include performing the CMP to expose at least a portion of the second interlayer insulating film 150.

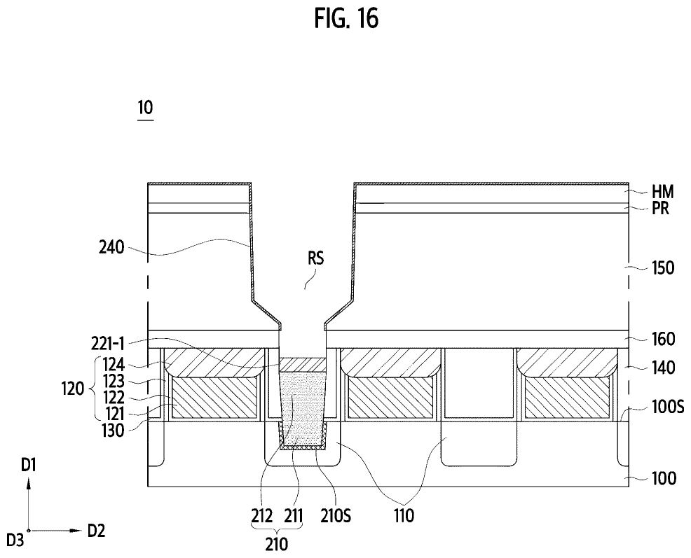

FIG. 16 is a drawing illustrating a semi-finished product to explain a method for manufacturing the semiconductor device 10 according to some example embodiments, and illustrates the process of forming the via area 1-1 221-1. In some example embodiments, in a method for manufacturing the semiconductor device 10, forming the wiring via 220 may include forming the via area 1-1 221-1 to make contact with the contact plug 210 in a portion of the area where the contact oxide film 210O has been removed. In some example embodiments, in a method for manufacturing the semiconductor device 10, in forming the wiring via 220, forming the via area 1-1 221-1 may include injecting a metal halide. In some example embodiments, the via area 1-1 221-1, may be formed at a flow rate of metal halide that is less than about or exactly 100 sccm, to for example, 1 sccm. Theoretically, this allows the via area 1-1 221-1 to have the aforementioned grain size.

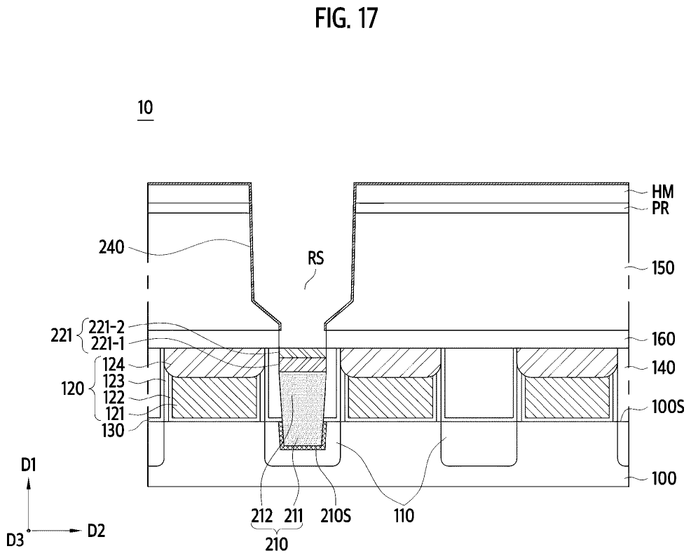

FIG. 17 is a drawing illustrating a semi-finished product to explain a method for manufacturing the semiconductor device 10 according to some example embodiments, and illustrates the process of forming the via area 1-2 221-2. In some example embodiments, in a method for manufacturing the semiconductor device 10, forming the wiring via 220 may include forming the via area 1-2 221-2 to be in contact with the via area 1-1 221-1. In some example embodiments, in a method for manufacturing the semiconductor device 10, in forming the wiring via 220, forming the via area 1-2 221-2 may include injecting a metal halide. In some example embodiments, the via area 1-2 221-2 may be formed at a flow rate of the metal halide that is about or exactly 300 sccm or greater, for example, about or exactly 1000 sccm. Theoretically, this allows the via area 1-2 221-2 to have the aforementioned grain size.

In some example embodiments, the ratio of flow (F₂, unit: sccm) of metal halide injected when forming the via area 1-2 221-2 to flow (F₁, unit: sccm) of metal halide injected when forming the via area 1-1 221-1 may be 3 or greater, for example, 100.

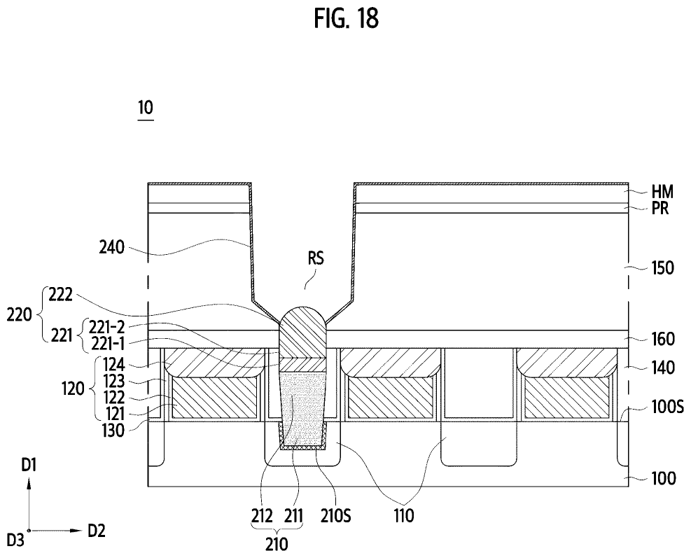

FIG. 18 is a drawing illustrating a semi-finished product to explain a method for manufacturing a semiconductor device according to some example embodiments, and illustrates the process of forming the wiring via 220. In some example embodiments, in a method for manufacturing the semiconductor device 10, forming the wiring via 220 may include forming the second via area 222. In some example embodiments, a method for manufacturing the semiconductor device 10 may include forming the via area 1-1 221-1 and then simultaneously or substantially simultaneously forming the via area 1-2 221-2 and the second via area 222. In some example embodiments, a method of manufacturing the semiconductor device 10 may include forming the second via area 222 after forming the via areas 1-2 221-2. In some example embodiments, in a method for manufacturing the semiconductor device 10, in forming the wiring via 220, forming the second via area 222 may include injecting a metal halide. In some example embodiments, the second via area 222 may be formed with a flow of metal halide at a flow rate about or exactly 300 sccm or greater, for example, about or exactly 1000 sccm. Theoretically, this allows the via area 1-2 221-2 to have the aforementioned grain size.

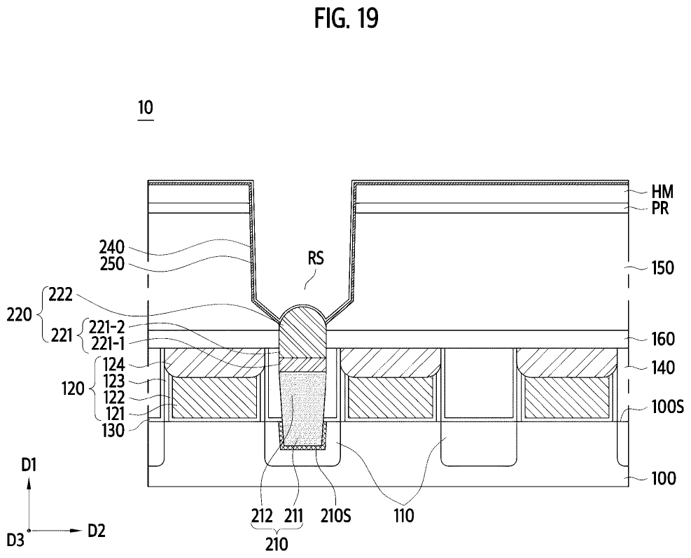

FIG. 19 is a drawing illustrating a semi-finished product to explain a method for manufacturing the semiconductor device 10 according to some example embodiments, and illustrates the process of forming the barrier film 250. In some example embodiments, a method of manufacturing the semiconductor device 10 may include forming the barrier film 250 over at least a portion of the protecting film 240 and the wiring via 220. In some example embodiments, the barrier film 250 may be formed via deposition. For example, the barrier film 250 may be formed by the CVD, the PVD and/or the ALD.

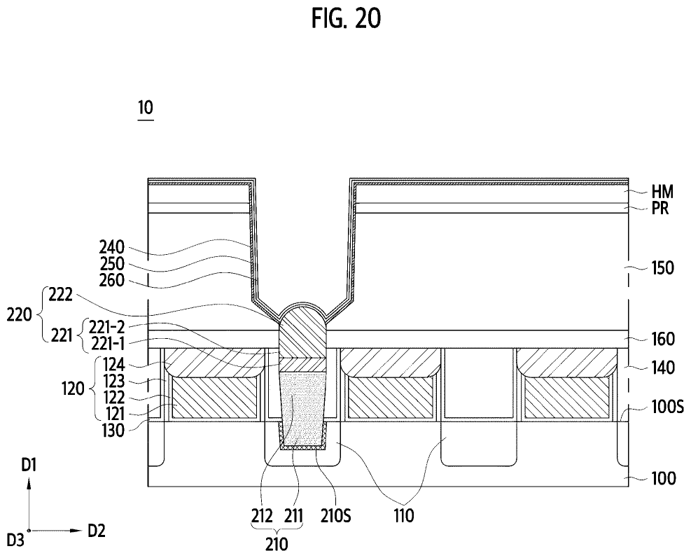

FIG. 20 is a drawing illustrating a semi-finished product to explain a method for manufacturing the semiconductor device 10 according to some example embodiments, and illustrates the process of forming the liner film 260. In some example embodiments, a method of manufacturing the semiconductor device 10 may include forming the liner film 260 over at least a portion of the barrier film 250. In some example embodiments, the liner film 260 may be formed via deposition. For example, the liner film 260 may be formed through the CVD, the PVD, and/or the ALD.

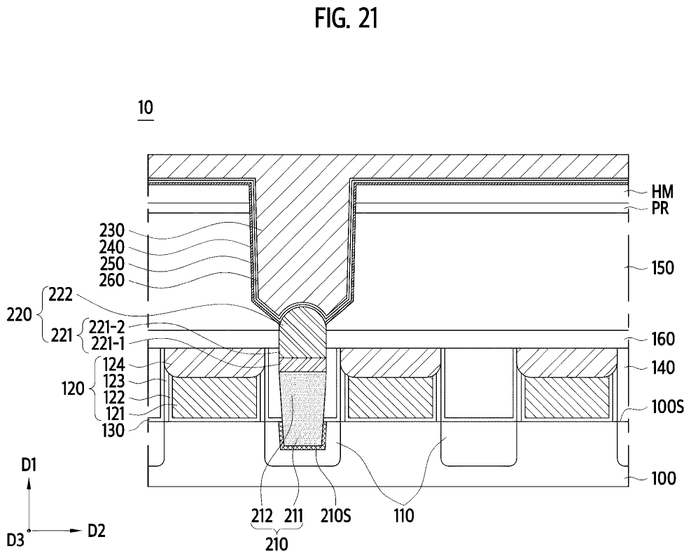

FIG. 21 is a drawing illustrating a semi-finished product to explain a method for manufacturing the semiconductor device 10 according to some example embodiments, and illustrates the process of forming the wiring line 230. In some example embodiments, a method of manufacturing the semiconductor device 10 may include forming the wiring line 230 to be electrically connected to the wiring via 220. In some example embodiments, the wiring line 230 may be formed through deposition. For example, the wiring line 230 may be formed through the CVD, the PVD, and/or the ALD. In some example embodiments, a method of manufacturing the semiconductor device 10 may include forming the wiring line 230 to fill the recessed portion RS.

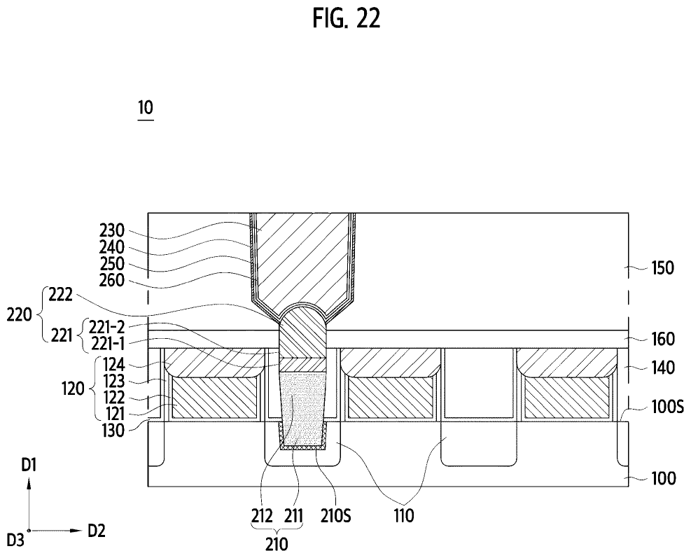

FIG. 22 is a drawing for explaining a method for manufacturing the semiconductor device 10 according to some example embodiments, and illustrates the result after the CMP. In some example embodiments, a method of manufacturing the semiconductor device 10 may include performing the CMP to expose at least a portion of the second interlayer insulating film 150.

According to some example embodiments, it is possible to provide a semiconductor device by which an insulating layer around a recess is protected and damage to the contact connected to a via is minimized or reduced, and provide a method of manufacturing the semiconductor device.

Effects of the present disclosure are not limited to those described above, and other effects may be made apparent to those skilled in the art from the following description.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical ideas or essential features. Therefore, the example embodiments described above should be understood in all respects as illustrative and not limiting.

What is claimed is:

1. A semiconductor device comprising:
a substrate;
a source/drain area on the substrate;
a first interlayer insulating film on the substrate;
a contact plug penetrating at least a portion of the first interlayer insulating film along a first direction perpendicular to a surface of the substrate and electrically connected to the source/drain area;
a second interlayer insulating film on the first interlayer insulating film;
a wiring via penetrating a portion of the second interlayer insulating film along the first direction and electrically connected to the contact plug;
a wiring line penetrating at least a portion of the second interlayer insulating film along the first direction and electrically connected to the wiring via; and
a protecting film between the wiring via and the second interlayer insulating film and between the wiring line and the second interlayer insulting film.

2. The semiconductor device of claim 1, further comprising an interlayer etching stopping film between the first interlayer insulating film and the second interlayer insulating film,
wherein the wiring via penetrates the interlayer etching stopping film along the first direction.

3. The semiconductor device of claim 1, wherein the contact plug comprises a first contact area surrounded by the source/drain area and a second contact area that is an area other than the first contact area,
further comprising a silicide layer between the first contact area of the contact plug and the source/drain area.

4. The semiconductor device of claim 1, wherein the protecting film comprises silicon oxide.

5. The semiconductor device of claim 1, further comprising a barrier film between the protecting film and the wiring line.

6. The semiconductor device of claim 5, wherein the barrier film surrounds at least a portion of the wiring via.

7. The semiconductor device of claim 5, further comprising a liner film between the barrier film and the wiring line.

8. The semiconductor device of claim 7, wherein the liner film surrounds at least a portion of the wiring via.

9. The semiconductor device of claim 1, wherein the wiring via further penetrates a portion of the first interlayer insulating film along the first direction.

10. The semiconductor device of claim 9, wherein
the wiring via comprises a first via area surrounded by the first interlayer insulating film and a second via area that is an area other than the first via area,
the first via area comprises a via area 1-1 that is adjacent to the contact plug and a via area 1-2 that is an area other than the via area 1-1, and
the via area 1-1 has a grain size that is smaller than a grain size of the via area 1-2.

11. The semiconductor device of claim 10, wherein
the via area 1-1 has a grain size measured according to a Zimmer method is greater than 0 nm² to 5 nm² or less, and
the via area 1-2 has a grain size measured according to the Zimmer method is greater than 5 nm² to 20 nm² or less.

12. The semiconductor device of claim 10, wherein the grain size of the via area 1-1 is smaller than the grain size of the second via area.

13. The semiconductor device of claim 12, wherein the grain size of the via area 1-2 is a same grain size as the grain size of the second via area.

14. The semiconductor device of claim 12, wherein the grain size of the second via area measured according to a Zimmer method is greater than 5 nm² to 20 nm² or less.

15. The semiconductor device of claim 1, wherein each of the wiring via and the contact plug has an electrical conductivity of 1×10⁶ S/m to 6×10⁷ S/m at 20° C.,
wherein the wiring via has a melting point higher than a melting point of the contact plug.

16. A method of manufacturing a semiconductor device, the method comprising:
forming a recessed portion in a semi-finished product comprising a substrate, a source/drain area on the substrate, a first interlayer insulating film on the substrate, a contact plug penetrating at least a portion of the first interlayer insulating film along a first direction perpendicular to a surface of the substrate and electrically connected to the source/drain area and a second interlayer insulating film on the first interlayer insulating film, by etching the second interlayer insulating film along the first direction until the contact plug is exposed;
forming a protecting film on at least an inner wall of the recessed portion;
forming a wiring via to be electrically connected to the contact plug; and
forming a wiring line to be electrically connected to the wiring via.

17. The method of manufacturing the semiconductor device of claim 16, wherein
forming the protecting film comprises forming a contact oxide film in a portion of the contact plug adjacent to the recessed portion,
forming the wiring via further comprises removing the contact oxide film.

18. The method of manufacturing the semiconductor device of claim 17, wherein forming the wiring via further comprises:
forming a via area 1-1 to contact the contact plug in a portion of an area where the contact oxide film is removed; and
forming a via area 1-2 on the via area 1-1.

19. The method of manufacturing the semiconductor device of claim 18, wherein, in forming the wiring via, each of forming the via area 1-1 and forming the via area 1-2 further comprises injecting metal halide,
wherein a ratio of flow, being F₂/F₁, F₁ being in units of sccm, F₂ being in units of sccm, for injecting the metal halide when forming the via area 1-2 and for injecting the metal halide when forming the via area 1-1 is 3 to 100.

20. A semiconductor device comprising:
a substrate;
a source/drain area on the substrate;
a first interlayer insulating film on the substrate;
a contact plug penetrating at least a portion of the first interlayer insulating film along a first direction perpendicular to a surface of the substrate and electrically connected to the source/drain area;
a second interlayer insulating film on the first interlayer insulating film;
a wiring via penetrating a portion of the second interlayer insulating film along the first direction and electrically connected to the contact plug;
a wiring line penetrating at least a portion of the second interlayer insulating film along the first direction and electrically connected to the wiring via;
a protecting film between the wiring via and the second interlayer insulating film and between the wiring line and the second interlayer insulting film, and the protecting film comprising silicon oxide;
a barrier film between the protecting film and the wiring line and surrounding at least a portion of the wiring via;
a liner film between the barrier film and the wiring line and surrounding at least a portion of the wiring via; and
an interlayer etching stopping film between the first interlayer insulating film and the second interlayer insulating film,
the wiring via penetrating a portion of the first interlayer insulating film and the interlayer etching stopping film along the first direction,
the wiring via comprising a first via area surrounded by the first interlayer insulating film and a second via area that is an area other than the first via area,
the first via area comprising a via area 1-1 that is adjacent to the contact plug and a via area 1-2 that is an area other than the via area 1-1,
the via area 1-1 having a grain size that is smaller than a grain size of the via area 1-2, and
the grain size of the via area 1-1 being smaller than the grain size of the second via area.
